(19) United States
(12) Patent Application Publication
(10) Pub. No.: US 2026/0164553 A1
(43) Pub. Date: Jun. 11, 2026

(54) PRINTED CIRCUIT BOARD

(71) Applicant: SAMSUNG ELECTRO-MECHANICS CO., LTD., Suwon-si (KR)

(72) Inventor: Yong Wan Ji, Suwon-si (KR)

(73) Assignee: SAMSUNG ELECTRO-MECHANICS CO., LTD., Suwon-si (KR)

(21) Appl. No.: 19/181,096

(22) Filed: Apr. 16, 2025

(30) Foreign Application Priority Data
Nov. 14, 2024 (KR) 10-2024-0162016

(51) Int. Cl. H05K 1/11; H05K 1/03

(52) U.S. Cl. CPC H05K 1/115; H05K 1/0306; H05K 2201/09563

(57) ABSTRACT

The present disclosure relates to a printed circuit board including: a glass layer having an upper surface and a lower surface, and a side surface connecting the upper surface and the lower surface; a through-hole penetrating between the upper surface and the lower surface of the glass layer; and a metal via filling at least a portion of the through-hole, where at least one of the upper surface and the lower surface of the glass layer, and at least one of the upper surface and the lower surface of the metal via respectively have a surface roughness greater than a surface roughness of a side surface of the glass layer.

### CROSS-REFERENCE TO RELATED APPLICATION(S)

This application claims the benefit of priority to Korean Patent Application No. 10-2024-0162016 filed on Nov. 14, 2024, in the Korean Intellectual Property Office, the disclosure of which is incorporated herein by reference in its entirety.

### TECHNICAL FIELD

The present disclosure relates to a printed circuit board.

### BACKGROUND

In order to respond to the high-performance and miniaturization strategies of semiconductors, the level of miniaturization and high-density required for printed circuit boards has increased. For example, in order to manufacture high-end products such as server boards, high-layer and large bodies are required. However, as the number of wiring layers increases and the body size increases, the board may become vulnerable to warpage. To solve this problem, the use of a glass core has been considered. However, since a surface of the glass is smooth, the adhesion with the insulating material may be low, and thus glass damage, voids, and delamination may occur.

### SUMMARY

An aspect of the present disclosure is to provide a printed circuit board capable of improving adhesion with an insulating material, and thus improving voids and delamination, in a substrate structure including a glass layer on which a metal via is formed.

One of the several solutions of the present disclosure is to form a surface roughness by performing a skiving operation on a surface of a glass layer and an exposed surface of a metal via using a laser.

For example, a printed circuit board may include: a glass layer having an upper surface and a lower surface, and a side surface connecting the upper surface and the lower surface; a through-hole penetrating between the upper surface and the lower surface of the glass layer; and a metal via filling at least a portion of the through-hole, and at least one of the upper surface and the lower surface of the glass layer, and at least one of the upper surface and the lower surface of the metal via may respectively have a surface roughness greater than a surface roughness of a side surface of the glass layer.

For example, a printed circuit board may include: a glass layer having an upper surface and a lower surface, and a side surface connecting the upper surface and the lower surface; a through-hole penetrating between the upper surface and the lower surface of the glass layer; and a metal via filling at least a portion of the through-hole, and the upper surface and the lower surface of the glass layer, and an upper surface and a lower surface of the metal via may respectively have an average roughness Ra of 0.1 μm or more and less than 10 μm.

One of the various effects of the present disclosure is to provide a printed circuit board which may improve adhesion to an insulating material, and may thus improve voids and delamination, in a substrate structure including a glass layer having a metal via formed therein.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 illustrates a top view image obtained by capturing a surface of a glass layer on which a metal via is formed with an electron microscope; and

FIG. 4 is a cross-sectional image of a cross-sectional surface taken along line A-A′ of the glass layer on which the metal via is formed in FIG. 3, captured with an electron microscope.

### DETAILED DESCRIPTION

Hereinafter, the present disclosure will be described with reference to the accompanying drawings. In the drawings, the shape and size of the elements may be exaggerated or reduced for clearer description.

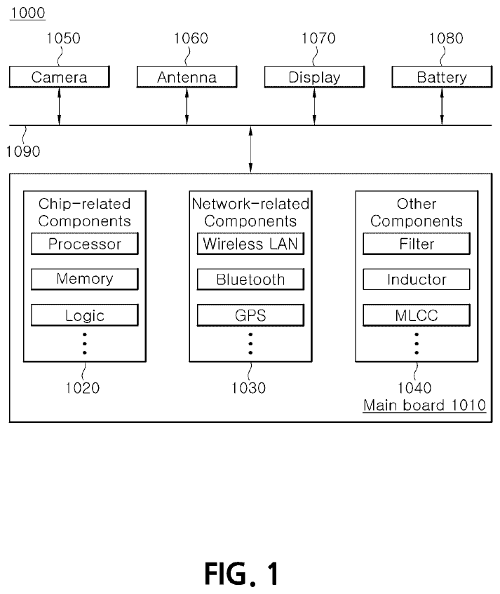

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. Additionally, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

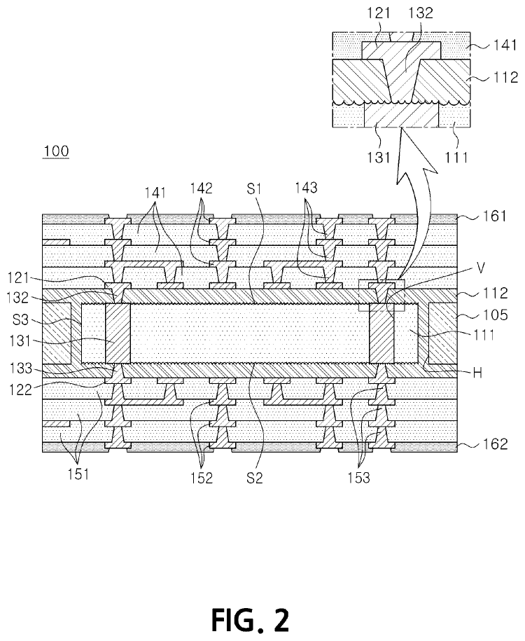

FIG. 2 is a cross-sectional view schematically illustrating an example of a printed circuit board.

Referring to FIG. 2, a printed circuit board 100 according to an example embodiment may include a glass layer 111 having an upper surface S1 and a lower surface S2 and a side surface S3 connecting the upper surface S1 and the lower surface S2, a through-hole V penetrating between the upper surface S1 and the lower surface S2 of the glass layer 111, and a metal via 131 filling at least a portion of the through-hole V. In this case, a surface roughness may be formed on the upper surface S1 and/or the lower surface S2 of the glass layer 111. Additionally, a surface roughness may also be formed on the upper surface and/or the lower surface of the metal via 131. For example, the upper surface S1 and/or the lower surface S2 of the glass layer 111 and an upper surface and/or a lower surface of the metal via 131 may have a greater surface roughness than that of the side surface S3 of the glass layer 111, respectively. For example, the upper surface S1 and/or the lower surface S2 of the glass layer 111 and the upper surface and/or the lower surface of the metal via 131 may be skived with a laser, as described below, and thus, an average roughness Ra thereof may be approximately 0.1 μm or more and less than 10 μm, or 0.1 μm or more and less than 2 μm. On the other hand, the side surface of the glass layer 111 may not be processed in this manner, and an average roughness Ra thereof may be 0.001 μm or more and less than 0.1 μm.

In this manner, the printed circuit board 100 according to an example embodiment may basically include a glass layer 111, and also, the metal via 131 may be formed in a landless form on the glass layer 111, that is, in a form without a separate pad or land, so that the microcircuit may be implemented more easily on an insulating material 112 described below, the process capability may be improved, and warpage control may be possible with a low thermal expansion coefficient. Additionally, in the printed circuit board 100 according to an example embodiment, a surface roughness may be formed on the upper surface and/or the lower surface of the glass layer 111, and a surface roughness may also be formed on the upper surface and/or the lower surface of the metal via 131 exposed from the glass layer 111. Accordingly, the adhesion between the glass layer 111 and the metal via 131 and the insulating material 112 described below may be improved, and accordingly, problems such as damage to the glass layer 111 and voids and delamination of the insulating material 112 may be improved. Additionally, the adhesion between the metal via 131 and the first and second connection vias 132 and 133 described below may also be improved, and thus, reliability may be further improved.

The surface roughness of the upper surface S1 and/or the lower surface S2 of the glass layer 111 and the upper surface and/or the lower surface of the metal via 131 may be formed by performing a skive operation using a laser. Both an ultraviolet laser and an infrared laser may be used as the laser. The roughness may be formed in both an X-direction and a Y-direction on a plane, and may be formed in only one direction, in the X-direction or the Y-direction if necessary. A size of the roughness may be adjusted depending on the laser source or energy amount. The roughness formation may be selectively formed in a desired region, and may be formed over a large area. In this case, the surface roughness of the upper surface of the glass layer 111 may be formed to be greater than the surface roughness of the upper surface of the metal via 131, and the surface roughness of the lower surface of the glass layer 111 may be formed to be greater than the surface roughness of the lower surface of the metal via 131, but the present disclosure is not necessarily limited thereto.

Referring to the drawings, the printed circuit board 100 according to an example embodiment may further include an insulating material 112 covering at least portions of each of the upper surface S1 and the lower surface S2 of the glass layer 111 and the upper surface and the lower surface of the metal via 131, a first wiring layer 121 disposed on an upper surface of the insulating material 112, a first connection via 132 penetrating through at least a portion of an upper side of the insulating material 112 and directly connecting at least a portion of the first wiring layer 121 to the upper surface of the metal via 131, a second wiring layer 122 disposed on a lower surface of the insulating material 112, and/or a second connection via 133 penetrating through at least a portion of a lower side of the insulating material 112 and directly connecting at least a portion of the second wiring layer 122 to the lower surface of the metal via 131. The glass layer 111 and the metal via 131 may be protected through the insulating material 112. Additionally, the first and second wiring layers 121 and 122 may be formed on the insulating material 112 instead of the glass layer 111, so that the reliability of the first and second wiring layers 121 and 122 may be improved by improving the adhesion, and the like, and more diverse designs may be applied. Additionally, the first and second connection vias 132 and 133 may be by directly connected to the metal via 131 without a pad or land, so that an entire thickness of the substrate may be made thinner, and a signal transmission path may be reduced.

The upper surface S1 and/or the lower surface S2 of the glass layer 111 and the upper surface and/or the lower surface of the metal via 131 may have a surface roughness greater than that of the upper surface and/or the lower surface of the insulating material 112, respectively. For example, the upper surface S1 and/or the lower surface S2 of the glass layer 111 and the upper surface and/or the lower surface of the metal via 131 may be skived with a laser as described above, so that each average roughness Ra may be approximately 0.1 μm or more and less than 10 μm, or 0.1 μm or more and 2 μm or less. On the other hand, in the case of the insulating material 112 that may include Ajinomoto build-up film (ABF), a surface roughness thereof, for example, the average roughness Ra may be approximately 400 nm to 800 nm.

Referring to the drawing, the printed circuit board 100 according to an example may further include a frame 105 having a through-portion H. The glass layer 111 may be at least partially disposed within the through-portion H. The insulating material 112 may cover at least a portion of each of an upper surface and a lower surface of the frame 105. The insulating material 112 may fill at least a portion between the frame 105 and the glass layer 111 within the through-portion H. If necessary, at least a portion between the frame 105 and the glass layer 111 within the through-portion H may also be filled with a separate filler. The frame 105 may include a material having excellent rigidity. The frame 105 may be used as a jig during the process, and thus the process may be performed on a panel level through the frame 105. Additionally, the frame 105 may remain in a final unit after singulation, which may be more advantageous for warpage control.

Referring to the drawings, the printed circuit board 100 according to an example embodiment may further include a plurality of first build-up insulating layers 141 disposed on the upper surface of the insulating material 112, a plurality of first build-up wiring layers 142 disposed on or within the plurality of first build-up insulating layers 141, and/or a plurality of first build-up via layers 143 respectively disposed within the plurality of first build-up insulating layers 141 and respectively connected to at least one of the plurality of first build-up wiring layers 142. For example, a build-up layer may be formed on an upper side of the glass layer 111. For example, the printed circuit board 100 may include the glass layer 111 as a core layer, and the build-up layer may be formed on at least one side of the core layer, and may be used as a package substrate, an interposer substrate or the like.

Referring to the drawings, the printed circuit board 100 according to an example embodiment may further include a plurality of second build-up insulating layers 151 disposed on the lower surface of the insulating material 112, a plurality of second build-up wiring layers 152 disposed on or within the plurality of second build-up insulating layers 151, and/or a plurality of second build-up via layers 153 respectively disposed within the plurality of second build-up insulating layers 151 and respectively connected to at least one of the plurality of second build-up wiring layers 152. For example, the printed circuit board 100 may include the glass layer 111 as a core layer, and may have build-up layers formed on both sides of the core layer, and may be used as a package substrate, an interposer substrate, or the like.

Referring to the drawings, the printed circuit board 100 according to an example embodiment may further include a first passivation layer 161 disposed on a first build-up insulating layer 141 disposed on an uppermost side, among the plurality of first build-up insulating layers 141, and having a first opening covering at least a portion of the first build-up wiring layer 142 disposed on an uppermost side, among the plurality of first build-up wiring layers 142, and exposing at least another portion thereof, and/or a second passivation layer 162 disposed on a second build-up insulating layer 151 disposed on a lowermost side, among the plurality of second build-up insulating layers 151, and having a second opening covering at least a portion of the second build-up wiring layer 152 disposed on a lowermost side, among a plurality of second build-up wiring layers 152, and exposing at least another portion thereof. Accordingly, the internal configuration of the printed circuit board 100 may be more easily protected.

Hereinafter, components of a printed circuit board 100 according to an example embodiment will be described in more detail with reference to the drawings.

The frame 105 may include an organic insulating material. The organic insulating material may include a thermosetting resin such as an epoxy resin, a thermoplastic resin such as a polyimide, or a resin together with an inorganic filler, an organic filler, and/or glass fiber (Glass Fiber, Glass Cloth or Glass Fabric). For example, the organic insulating material may include a Copper Clad Laminate (CCL) or an Unclad CCL, but the present disclosure is not limited thereto, and may also include other organic or inorganic materials having excellent rigidity. The through-portion H may penetrate between the upper surface and the lower surface of the frame 105. The through-portion H may continuously surround the side surface S3 of the glass layer 111.

The glass layer 111 may include glass, which is an amorphous solid. The glass may include, for example, pure silicon dioxide (about 100% SiO₂), soda-lime glass, borosilicate glass, and alumino-silicate glass. However, the present disclosure is not limited thereto, and alternative glass materials, for example, fluorine glass, phosphate glass, chalcogen glass, or the like, may also be used as materials. Additionally, other additives may be further included to form a glass having specific physical properties. Such additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these elements and other elements. The glass layer 111 may be distinguished from organic insulating materials including glass fiber (Glass Fiber, Glass Cloth or Glass Fabric), such as Copper Clad Laminate (CCL), Prepreg (PPG), or the like. The glass layer 111 may be, for example, in the form of a glass plate. The through-hole V may penetrate between the upper surface and the lower surface of the glass layer 111. The number of side surfaces S3 may be one or plural depending on the shape of the glass layer 111. For example, when the glass layer 111 has a roughly rectangular shape on a plane, the side surface S3 may be provided in plural, for example, four side surfaces S3s may be provided, but the present disclosure is not limited thereto. When the glass layer 111 has a roughly elliptical shape on a plane, the number of the side surface S3 may be one, but the present disclosure is not limited thereto.

The insulating material 112 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) along with the resin. For example, the organic insulating material may include Prepreg (PPG), an Ajinomoto Build-up Film (ABF), and Photoimageable Dielectric (PID), but the present disclosure is not limited thereto. The insulating material 112 may be formed of a plurality of layers. In this case, each of the plurality of layers may be integrated without a boundary, or the boundary between the layers may be identified. Additionally, the plurality of layers may include substantially the same insulating material, or may include different insulating materials.

Each of the first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. For example, each of the first and second wiring layers 121 and 122 may include chemical copper formed by electroless plating as a seed layer, and may include electrolytic copper formed by electrolytic plating as a pattern plating layer based thereon. Each of the first and second wiring layers 121 and 122 may perform various functions according to the design. For example, the first and second wiring layers 121 and 122 may include a signal pattern, a power pattern, and a ground pattern. Each of the patterns may have various shapes such as a line, a trace, a plane, a land, and a pad.

The metal via 131 may include a metal. The metal may include copper (Cu), aluminum (Al), silver (Ag), tin (Sn), gold (Au), nickel (Ni), lead (Pb), titanium (Ti), and/or alloys thereof. For example, the metal via 131 may include a titanium layer and a copper layer formed by sputtering, that is, sputtered titanium and sputtered copper, as seed layers, and may include electrolytic copper formed by electrolytic plating as a pattern plating layer based on the titanium layer and the copper layer. The metal via 131 may perform various functions depending on the design. For example, the metal via 131 may include a through-via for signal transmission, a through-via for power transmission, and a through-via for ground transmission. The metal via 131 may include a filled VIA in which the through-hole V is filled with a metal. The metal via 131 may have a cylindrical shape, but may also have an hourglass shape. There may be a plurality of metal vias 131.

Each of the first and second connection vias 132 and 133 may include a metal. The metal may include copper (Cu), aluminum (Al), silver (Ag), tin (Sn), gold (Au), nickel (Ni), lead (Pb), titanium (Ti), and/or alloys thereof. For example, each of the first and second connection vias 132 and 133 may include chemical copper formed by electroless plating as a seed layer, and may include electrolytic copper formed by electrolytic plating based on the chemical copper as a pattern plating layer. Each of the first and second connection vias 132 and 133 may perform various functions depending on the design. For example, the first and second connection vias 132 and 133 may include a connection via for signal transmission, a connection via for power transmission, and a connection via for ground transmission. Each of the first and second connecting vias 132 and 133 may include a filled VIA in which the via hole is filled with a metal, but may also include a conformal VIA in which the metal is disposed along a wall surface of the via hole. The first and second connecting vias 132 and 133 may have shapes that are tapered in opposite directions. Each of the first and second connecting vias 132 and 133 may be provided in plural.

Each of the plurality of first and second build-up insulating layers 141 and 151 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may be Prepreg (PPG), an Ajinomoto Build-up Film (ABF), Photoimageable Dielectric (PID), or the like, but the present disclosure is not limited thereto. Each of the plurality of first and second build-up insulating layers 141 and 151 may be formed of a plurality of layers. In this case, each of the plurality of layers may be integrated without a boundary, or the boundaries between the layers may be identified. Additionally, each of the multiple layers may include substantially the same insulating material, but may also include different insulating materials. The plurality of first and second build-up insulating layers 141 and 151 may have the same number of layers, but the present disclosure is not limited thereto, and the plurality of first build-up insulating layers 141 may have a relatively larger number of layers.

Each of the plurality of first and second build-up wiring layers 142 and 152 may include a metal. The metal may include copper (Cu), aluminum (Al), silver (Ag), tin (Sn), gold (Au), nickel (Ni), lead (Pb), titanium (Ti), and/or alloys thereof. For example, each of the plurality of first and second build-up wiring layers 142 and 152 may include chemical copper formed by electroless plating as a seed layer, and may include electrolytic copper formed by electrolytic plating based on the chemical copper as a pattern plating layer. Each of the plurality of first and second build-up wiring layers 142 and 152 may perform various functions according to the design. For example, the plurality of first and second build-up wiring layers 142 and 152 may include a signal pattern, a power pattern, and a ground pattern. Each of the patterns may have various shapes such as a line, a trace, a plane, a land, a pad, and the like. The plurality of first and second build-up wiring layers 142 and 152 may have the same number of layers, but the plurality of first build-up wiring layers 142 may have a relatively greater number of layers.

Each of the first and second build-up via layers 143 and 153 may include a metal. The metal may include copper (Cu), aluminum (Al), silver (Ag), tin (Sn), gold (Au), nickel (Ni), lead (Pb), titanium (Ti), and/or alloys thereof. For example, each of the first and second build-up via layers 143 and 153 may include chemical copper formed by electroless plating as a seed layer, and may include electrolytic copper formed by electrolytic plating based on the chemical copper as a pattern plating layer. Each of the first and second build-up via layers 143 and 153 may perform various functions according to a design. For example, the first and second build-up via layers 143 and 153 may include a connection via for signal transmission, a connection via for power transmission, and a connection via for ground transmission. Each of the plurality of first and second build-up via layers 143 and 153 may include a filled VIA in which the via hole is filled with a metal, but may also include a conformal VIA in which the metal is disposed along a wall surface of the via hole. Each of the plurality of first and second build-up via layers 143 and 153 may include a plurality of connection vias. The connection vias included in each of the plurality of first build-up via layers 143 may have a shape that is tapered in an opposite direction to the connection vias included in each of the plurality of second build-up via layers 153. The plurality of first and second build-up via layers 143 and 153 may have the same number of layers, but the plurality of first build-up via layers 143 may also have a relatively greater number of layers.

Each of the first and second passivation layers 161 and 162 may include an organic insulating material. The organic insulating material may include a thermosetting resin such as an epoxy resin, a thermoplastic resin such as a polyimide, or an inorganic filler and/or an organic filler together with the resin. For example, the organic insulating material may be an Ajinomoto Build-up Film (ABF), Photoimageable Dielectric (PID), Solder Resist (SR), or the like, but the present disclosure is not limited thereto. Each of the first and second passivation layers 161 and 162 may be formed of a plurality of layers. Each of the first and second passivation layers 161 and 162 may have a plurality of openings, and a pattern exposed through each of the openings may be a Solder Mask Defined (SMD) type and/or a Non Solder Mask Defined (NSMD) type, but the present disclosure is not limited thereto.

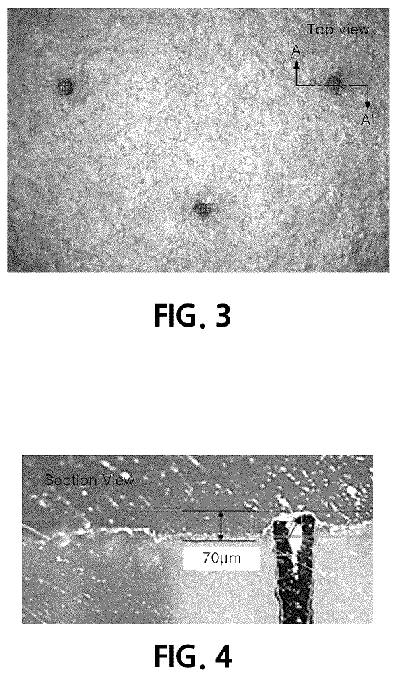

FIG. 3 illustrates a top view image obtained by capturing a surface of a glass layer on which a metal via is formed with an electron microscope; and

FIG. 4 is a cross-sectional image of a cross-sectional surface taken along line A-A′ of the glass layer on which the metal via is formed in FIG. 3, captured with an electron microscope.

Referring to the images, a surface roughness may be formed on the surface of the glass layer and the surface of the metal via. For example, as described above, the surface of the glass layer and the surface of the metal via may be skived using a laser to form roughness. In this case, the upper surface of the glass layer and the upper surface of the metal via may have a height difference of 10 μm or more and less than 100 μm, 30 μm or more and less than 90 μm, or 50 μm or more and less than 80 μm. For example, during the skiving process, at least a portion of the upper surface of the glass layer may be removed more than at least another portion, resulting in a significant height difference exceeding the range of the surface roughness, for example, the surface roughness Ra described above. The surface roughness may be formed on at least a portion of the upper surface of the glass layer and at least another portion thereof within the height difference. Additionally, the metal via may have a landless structure, and at the same time, an upper surface thereof may further protrude than at least a portion of the upper surface of the glass layer. For example, a structure may be implemented in which the glass layer around the metal via is removed during the skive process so that the metal via protrudes. For example, the upper surface of the metal via may further protrude than at least a portion of the upper surface of the glass layer by 10 μm or more and less than 100 μm, 30 μm or more and less than 90 μm, or 50 μm or more and less than 80 μm. The above-described content may be applied not only to the upper surface of the glass layer and the upper surface of the metal via, but also to the lower surface of the glass layer and the lower surface of the metal via. The electron microscope may use a Scanning Electron Microscope (SEM) or a Transmission Electron Microscope (TEM). These technical contents may be applied to the printed circuit board 100 according to the above-described example.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component.

In the present disclosure, being disposing in a cavity portion, a cavity, a through-portion or a through-hole may include not only a case in which an object is disposed completely in the cavity portion, the cavity, the through-portion or the through-hole, but also a case in which the object protrudes upwardly or downwardly in a cross-section. For example, when the object may be disposed within the cavity portion, the cavity, the through-portion or the through-hole on a plane, the object may be determined to be disposed within the cavity portion, the cavity, the through-portion or the through-hole in a broader sense.

In the present disclosure, determination may be performed by including process errors, positional deviations, errors at the time of measurement, which may occur in a manufacturing process. For example, substantially the same direction may include not only the completely same direction but also the approximately the same direction. Furthermore, substantially coplanar may include not only the case of being completely coplanar but also the case of being approximately coplanar. Furthermore, substantially having a specific shape may include not only the case of having such a shape completely but also the case of having such a shape approximately. Furthermore, substantially the same insulating material may mean not only the case of being the completely same insulating material but also the case of including the same type of insulating material. Accordingly, the composition of the insulating material may be substantially the same, but the specific composition ratio thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer having an upper surface, a lower surface, and a side surface connecting the upper surface and the lower surface;
a through-hole penetrating between the upper surface and the lower surface of the glass layer; and
a metal via filling at least a portion of the through-hole,
wherein at least one of the upper surface and the lower surface of the glass layer, and at least one of the upper surface and the lower surface of the metal via respectively have a surface roughness greater than a surface roughness of a side surface of the glass layer.

2. The printed circuit board according to claim 1,
wherein each of the upper surface and the lower surface of the glass layer, and each of the upper surface and the lower surface of the metal via have a surface roughness greater than a surface roughness of the side surface of the glass layer.

3. The printed circuit board according to claim 2,
wherein the upper surface of the glass layer has a surface roughness greater than a surface roughness of the upper surface of the metal via, and
a lower surface of the glass layer has a surface roughness greater than the lower surface of the metal via.

4. The printed circuit board according to claim 2,
wherein the upper surface and the lower surface of the glass layer, and the upper surface and the lower surface of the metal via, respectively have an average roughness Ra in a range from 0.1 μm to 10 μm.

5. The printed circuit board according to claim 2,
wherein the side surface of the glass layer has an average roughness Ra in a range from 0.001 μm to 0.1 μm.

6. The printed circuit board according to claim 1, further comprising:
an insulating material covering at least portions of each of the upper surface and the lower surface of the glass layer and the upper surface and the lower surface of the metal via;
a first wiring layer disposed on an upper surface of the insulating material;
a first connection via penetrating through at least a portion of an upper side of the insulating material and directly connecting at least a portion of the first wiring layer to the upper surface of the metal via;
a second wiring layer disposed on a lower surface of the insulating material;
a second connection via penetrating through at least a portion of a lower side of the insulating material and directly connecting at least a portion of the second wiring layer to the lower surface of the metal via.

7. The printed circuit board according to claim 6,
wherein each of the upper surface and the lower surface of the glass layer, and each of the upper surface and the lower surface of the metal via have a surface roughness greater than a surface roughness of each of the upper surface and the lower surface of the insulating material.

8. The printed circuit board according to claim 6, further comprising:
a frame having a through-portion,
wherein the glass layer is at least partially disposed within the through-portion, and
the insulating material covers at least portions of each of an upper surface and a lower surface of the frame, and fills at least a portion between the frame and the glass layer within the through-portion.

9. The printed circuit board according to claim 6, further comprising:
a plurality of first build-up insulating layers disposed on the upper surface of the insulating material;
a plurality of first build-up wiring layers respectively disposed on or within the plurality of first build-up insulating layers; and
a plurality of first build-up via layers respectively disposed within the plurality of first build-up insulating layers, and respectively connected to at least one of the plurality of first build-up wiring layers.

10. The printed circuit board according to claim 9, further comprising:
a plurality of second build-up insulating layers disposed on the lower surface of the insulating material;
a plurality of second build-up wiring layers respectively disposed on or within the plurality of second build-up insulating layers; and
a plurality of second build-up via layers respectively disposed within the plurality of second build-up insulating layers, and respectively connected to at least one of the plurality of second build-up wiring layers.

11. A printed circuit board, comprising:
a glass layer having an upper surface and a lower surface, and a side surface connecting the upper surface and the lower surface;
a through-hole penetrating between the upper surface and the lower surface of the glass layer; and
a metal via filling at least a portion of the through-hole,
wherein the upper surface and the lower surface of the glass layer, and an upper surface and a lower surface of the metal via respectively have an average roughness Ra in a range from 0.1 μm to 10 μm.

12. The printed circuit board according to claim 11,
wherein the upper surface and the lower surface of the glass layer, and the upper surface and the lower surface of the metal via respectively have an average roughness Ra in a range from 0.1 μm to 2 μm.

13. The printed circuit board according to claim 11,
wherein at least a portion of the upper surface of the glass layer and at least another portion of the upper surface have a height difference beyond a range of an average roughness Ra formed on the upper surface of the glass layer.

14. The printed circuit board according to claim 11,
wherein the metal via has a landless structure.

15. The printed circuit board according to claim 14,
wherein the upper surface of the metal via further protrudes than at least a portion of the upper surface of the glass layer.

16. The printed circuit board according to claim 11, further comprising:
an insulating material covering at least portions of each of the upper surface and the lower surface of the glass layer and the upper surface and the lower surface of the metal via;
a first wiring layer disposed on an upper surface of the insulating material;
a first connection via penetrating through at least a portion of an upper side of the insulating material and directly connecting at least a portion of the first wiring layer to the upper surface of the metal via;
a second wiring layer disposed on a lower surface of the insulating material; and
a second connection via penetrating through at least a portion of a lower side of the insulating material and directly connecting at least a portion of the second wiring layer to the lower surface of the metal via.

17. The printed circuit board according to claim 16, further comprising:
a frame having a through-portion,
wherein the glass layer is at least partially disposed within the through-portion, and
the insulating material covers at least portions of each of an upper surface and a lower surface of the frame, and fills at least a portion between the frame and the glass layer within the through-portion.

18. A printed circuit board, comprising:
a glass layer having a top surface, a bottom surface and a side surface connecting the top and bottom surfaces, a surface roughness of the top and/or bottom surfaces being greater than a surface roughness of the side surface;
a through-hole penetrating through the glass layer between the top and bottom surfaces; and
a metal via at least partially filling the through-hole,
wherein, in a cross-section view, a top surface of the metal via protrudes above the top surface of the glass layer by a distance greater than the surface roughness of the top surface of the glass layer.

19. The printed circuit board of claim 18, wherein a surface roughness of the top surface of the metal via is greater than the surface roughness of the side surface of the glass layer and smaller than the surface roughness of the top and/or bottom surface of the glass layer.

20. The printed circuit board of claim 18, wherein a distance between the top surface of the metal via and the top surface of the glass layer in the cross-section view is in a range from 10 μm to 100 μm.
